(19) United States
(12) Patent Application Publication
(10) Pub. No.: US 2009/0077782 A1
(43) Pub. Date: Mar. 26, 2009

(54) METHOD FOR PRODUCING ACTUATOR DEVICE AND METHOD FOR PRODUCING LIQUID EJECTING HEAD

(75) Inventor: Motoki TAKABE, Shiojiri-shi (JP)

Correspondence Address: Workman Nydegger;1000 Eagle Gate Tower, 60 East South Temple, Salt Lake City, UT, 84111, US

(73) Assignee: Seiko Epson Corporation, Tokyo (JP)

(21) Appl. No.: 12/234,338

(22) Filed: Sep. 19, 2008

(30) Foreign Application Priority Data
Sep. 20, 2007 (JP) 2007-244428

(51) Int. Cl. H01L 41/22

(52) U.S. Cl. 29/25.35

(57) ABSTRACT

A method for producing an actuator device includes forming a lower electrode above a substrate, forming thereon a piezoelectric layer including multiple piezoelectric films by repeatedly sintering a piezoelectric precursor film containing titanium, zirconium, and lead, and forming an upper electrode above the piezoelectric layer. A titanium seed layer is formed above the lower electrode and a piezoelectric precursor film is crystallized by sintering to form a first piezoelectric layer above the titanium seed layer. An intermediate titanium seed layer is formed above the first piezoelectric layer and a piezoelectric precursor film is crystallized by sintering, forming a second piezoelectric layer above the intermediate titanium seed layer. At least one piezoelectric precursor film is stacked above the second piezoelectric layer and crystallized by sintering at a temperature higher than a temperature at which the first and second piezoelectric layers are formed, thereby forming a third piezoelectric layer.

### CROSS REFERENCES TO RELATED APPLICATIONS

The present invention contains subject matter related to Japanese Patent Application No. 2007-244428 filed in the Japanese Patent Office on Sep. 20, 2007, the entire contents of which are incorporated herein by reference.

### BACKGROUND

1. Technical Field

The present invention relates to a method for producing an actuator device including a piezoelectric element displaceably provided above a substrate, the piezoelectric element including a lower electrode, a piezoelectric layer, and an upper electrode. The invention also relates to a method for producing a liquid ejecting head including an actuator device serving as a liquid ejecting device.

2. Related Art

An example of piezoelectric elements used for actuator devices is an element in which a piezoelectric layer, having the function of electromechanical transduction, composed of a piezoelectric material such as a crystallized dielectric material, e.g., lead zirconate titanate is arranged between two electrodes: a lower electrode and an upper electrode. Such actuator devices are referred to generally as actuator devices that vibrate in a flexural mode. For example, these actuator devices are used in liquid ejecting heads.

A typical example of a liquid ejecting head is an ink jet recording head that includes a vibrating plate constituting part of a pressure-generating chamber communicating with a nozzle opening for ejection of ink droplets and that ejects ink droplets from the nozzle opening by deforming the vibrating plate with the piezoelectric element and pressurizing ink in the pressure-generating chamber. An example of actuator devices mounted on ink jet recording heads is an actuator device including piezoelectric elements produced by forming a uniform piezoelectric layer by a film-forming technique above the entire surface of a vibrating plate and separating the piezoelectric layer by lithography in such a manner that individual piezoelectric elements have a shape corresponding to each pressure-generating chamber.

The piezoelectric layer (piezoelectric film) is composed of, for example, a ferroelectric material such as lead zirconate titanate (PZT). Such a piezoelectric layer is formed by, for example, a procedure described below. Titanium crystals are formed by sputtering or the like above a lower electrode. A piezoelectric precursor film as the first layer is formed above the titanium crystals by a sol-gel method. The piezoelectric precursor film is fired to form the first piezoelectric film. Titanium crystals are formed above the first piezoelectric film. Piezoelectric films as the second and subsequent layers are stacked above the titanium crystals to form a piezoelectric layer having a predetermined thickness (for example, see JP-A-2003-174211 (claim 14)).

The piezoelectric layer, unfortunately, has regions (unstable composition phases) with high titanium concentrations in the vicinity of interfaces between the lower electrode and the first piezoelectric film and between the first piezoelectric film and the second piezoelectric film. The piezoelectric film with a high titanium concentration does not easily deform. That is, the unstable composition phase inhibits the deformation of the piezoelectric layer. As a result, an actuator device having stable displacement properties cannot be provided.

Furthermore, the piezoelectric layer does not easily deform in the unstable composition phases in the vicinity of the interfaces described above but deforms easily in a region other than the unstable composition phases. This results in a stress difference between the unstable composition phases and the other region, thereby disadvantageously causing the formation of cracks in the piezoelectric layer and leading to a reduction in reliability.

### SUMMARY

An advantage of some aspects of the invention is that it provides a method for producing an actuator device having improved reliability and a method for producing a liquid ejecting head.

According to a first aspect of the invention, a method for producing an actuator device includes forming a lower electrode above a substrate, forming a piezoelectric layer including a plurality of piezoelectric films on the lower electrode by repeatedly forming a piezoelectric film by sintering a piezoelectric precursor film containing titanium, zirconium, and lead, and forming an upper electrode above the piezoelectric layer. In forming the piezoelectric layer, the method further includes forming a titanium seed layer avobe the lower electrode and crystallizing a piezoelectric precursor film by sintering to form a first piezoelectric layer above the titanium seed layer, forming an intermediate titanium seed layer above the first piezoelectric layer and crystallizing a piezoelectric precursor film by sintering to form a second piezoelectric layer above the intermediate titanium seed layer, and stacking at least one piezoelectric precursor film above the second piezoelectric layer and crystallizing the at least one piezoelectric precursor film by sintering at a temperature higher than a temperature at which the first and second piezoelectric layers are formed by sintering, so that a third piezoelectric layer is formed.

In this case, the first piezoelectric layer and the second piezoelectric layer are fired at a temperature lower than a temperature at which the third piezoelectric layer is formed by sintering. This prevents the formation of the unstable composition phase in the piezoelectric layer, thereby improving the displacement properties and reliability of the actuator device.

Preferably, the first piezoelectric layer has a thickness 5 to 40 times that of the titanium seed layer, the second piezoelectric layer has a thickness 5 to 40 times that of the intermediate titanium seed layer, and the first and second piezoelectric layers are formed by sintering at 630° C. to 680° C. This prevents the formation of the unstable composition phase and results in the first piezoelectric layer having a titanium concentration of about 60%.

Preferably, the method according to a first aspect of the invention further includes after forming the first piezoelectric layer, simultaneously patterning the lower electrode and the first piezoelectric layer. The intermediate titanium seed layer is formed above the substrate including the patterned first piezoelectric layer. In this case, it is possible to form a piezoelectric layer having satisfactory crystallinity.

According to a second aspect of the invention, a method for producing a liquid ejecting head including a channel-forming substrate provided with a pressure-generating chamber communicating with a nozzle opening and including a liquid ejecting unit that produces a change in the pressure in the pressure-generating chamber. The liquid ejecting unit is formed by the method for producing an actuator device according to the first aspect.

In this case, it is possible to produce a liquid ejecting head having improved liquid ejecting properties and reliability.

### BRIEF DESCRIPTION OF THE DRAWINGS

The invention will be described with reference to the accompanying drawings, wherein like numbers reference like elements.

FIG. 1 is a schematic exploded perspective view of a recording head according to a first embodiment.

FIGS. 2A and 2B are a plan view and a cross-sectional view of a recording head according to the first embodiment.

FIGS. 3A to 3C are cross-sectional views illustrating a method for producing a recording head according to the first embodiment.

FIGS. 4A to 4C are cross-sectional views illustrating the method for producing a recording head according to the first embodiment.

FIGS. 5A to 5D are cross-sectional views illustrating the method for producing a recording head according to the first embodiment.

FIGS. 6A to 6C are cross-sectional views illustrating the method for producing a recording head according to the first embodiment.

FIGS. 7A and 7B are cross-sectional views illustrating the method for producing a recording head according to the first embodiment.

FIGS. 8A and 8B are cross-sectional views illustrating the method for producing a recording head according to the first embodiment.

FIGS. 9A to 9C are graphs each showing the relationship between the titanium concentration in a piezoelectric layer and the distance from a lower electrode.

FIGS. 10A and 10B are graphs each showing the relationship between the titanium concentration in a piezoelectric layer and the distance from a lower electrode.

### DESCRIPTION OF EXEMPLARY EMBODIMENTS

The invention will be described in detail below on the basis of embodiments.

### First Embodiment

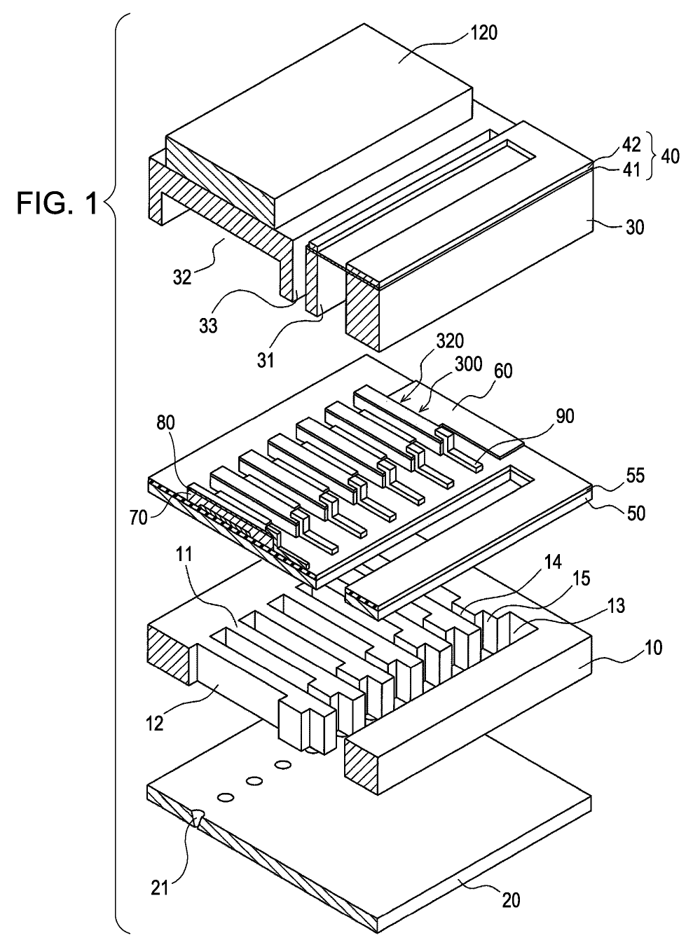

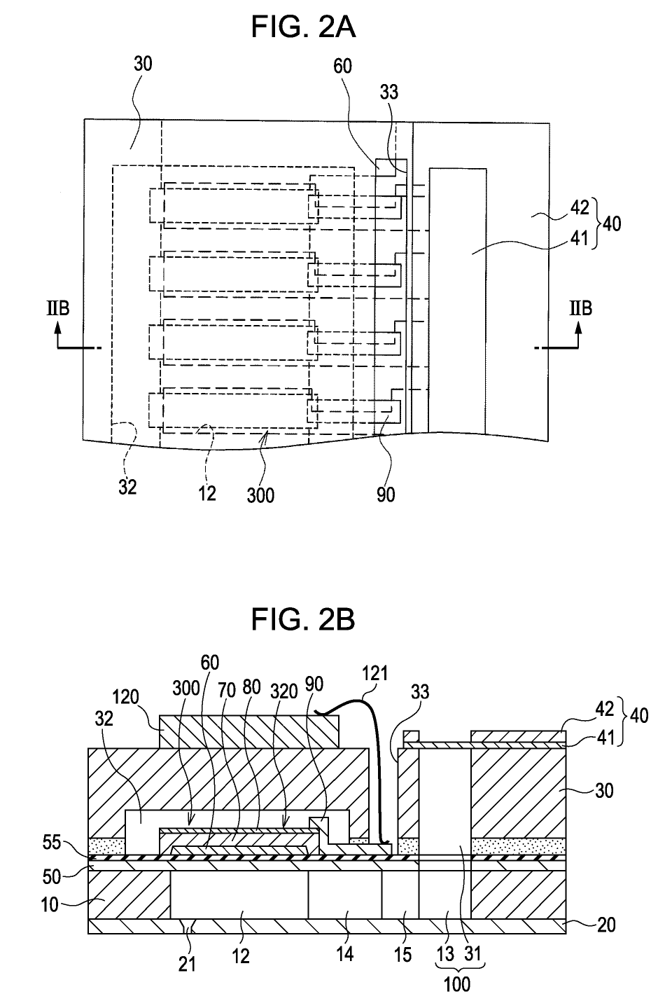

FIG. 1 is a schematic exploded perspective view of an ink-jet recording head as an example of a liquid ejecting head according to a first embodiment of the invention. FIG. 2A is a plan view, and FIG. 2B is a cross-sectional view taken along line IIB-IIB in FIG. 2A.

As shown in the figures, a channel-forming substrate 10 is made of a (110)-oriented single-crystal silicon substrate in this embodiment. A resilient film 50 composed of silicon dioxide formed by thermal oxidation in advance and having a thickness of 0.5 to 2.0 μm is formed above one surface of the channel-forming substrate 10.

The channel-forming substrate 10 includes pressure-generating chambers 12 partitioned with a plurality of partitions 11 formed by anisotropic etching from the other surface, the pressure-generating chambers 12 being arranged in the width direction (transverse direction) thereof. An ink supply channel 14 (liquid supply channel) and a communicating channel 15, which are partitioned with the partitions 11, are arranged on an end of each of the pressure-generating chambers 12 of the channel-forming substrate 10 in the longitudinal direction. A communicating portion 13 is formed at an end of each of the communicating channels 15, the communicating portion 13 partially constituting a reservoir 100 that serves as a common ink chamber (liquid chamber) for each of the pressure-generating chambers 12. That is, the channel-forming substrate 10 includes a liquid passage formed of the pressure-generating chambers 12, the communicating portion 13, the ink supply channels 14, and the communicating channels 15.

Each of the ink supply channels 14 communicates with an end of a corresponding one of the pressure-generating chambers 12 in the longitudinal direction and has a cross-sectional area smaller than that of a corresponding one of the pressure-generating chambers 12. For example, in this embodiment, each of the ink supply channels 14 is formed so as to have a width smaller than that of a corresponding one of the pressure-generating chambers 12 by reducing the width of a passage that is located between the reservoir 100 and the corresponding pressure-generating chamber 12 and that is located adjacent to the corresponding pressure-generating chamber 12. In this embodiment, each ink supply channel 14 is formed by reducing the width of the passage from one side thereof. Alternatively, each ink supply channel may be formed by reducing the width of the passage from both sides thereof. Furthermore, the passage may not be reduced in the width direction but may be reduced in the thickness direction to form the ink supply channel. Each of the communicating channels 15 communicates with a side of the corresponding ink supply channel 14 opposite the side adjacent to the corresponding pressure-generating chamber 12 and has a cross-sectional area larger than that of each ink supply channel 14 in the width direction (transverse direction). In this embodiment, each communicating channel 15 has a cross-sectional area equal to that of a corresponding one of the pressure-generating chambers 12.

That is, the channel-forming substrate 10 includes the pressure-generating chambers 12, the ink supply channels 14 each having a cross-sectional area smaller than that of a corresponding one of the pressure-generating chambers 12 in the transverse direction, the communicating channels 15 communicating with the ink supply channels 14 and each having a cross-sectional area larger than that of a corresponding one of the ink supply channels 14 in the transverse direction, and the plurality of partitions 11 partitioning these components.

A nozzle plate 20 having nozzle openings 21 is bonded to an opening side of the channel-forming substrate 10 using, for example, an adhesive or a heat-sealing film, each of the nozzle openings 21 communicating with a portion in the vicinity of an end of a corresponding one of the pressure-generating chambers 12 remote from the ink supply channels 14. The nozzle plate 20 has a thickness of, for example, 0.01 to 1 mm and is composed of, for example, a glass ceramic material, a silicon single crystal, or stainless steel having a linear expansion coefficient of, for example, 2.5 to 4.5 (×10⁻⁶/° C.) at 300° C. or lower.

As described above, the resilient film 50 having a thickness of, for example, about 1.0 μm is arranged on a side of the channel-forming substrate 10 opposite the opening side thereof. The resilient film 50 is overlaid with an insulating film 55 having a thickness of, for example, about 0.4 μm. Piezoelectric elements 300 are formed above the insulating film 55, each of the piezoelectric elements 300 including a lower electrode film 60 having a thickness of, for example, about 0.2 μm, a piezoelectric layer 70 having a thickness of, for example, about 1.1 μm, and an upper electrode film 80 having a thickness of, for example, about 0.05 μm stacked by a process described below. Each of the piezoelectric elements 300 indicates a portiabove including the lower electrode film 60, the piezoelectric layer 70, and the upper electrode film 80. In general, one of the electrodes of each piezoelectric element 300 is used as a common electrode. The other electrode and each piezoelectric layer 70 are formed by patterning with respect to each pressure-generating chamber 12. Portions each including the patterned electrode and piezoelectric layer 70 and deformed by applying a voltage to both electrodes is referred to as piezoelectric active portions. In this embodiment, the lower electrode film 60 is used as the common electrode for the piezoelectric elements 300, and the upper electrode films 80 are used as individual electrodes for the piezoelectric elements 300. Alternatively, a reverse arrangement for the sake of a driving circuit and interconnections may be used without any problem. In this embodiment, portions each including each of the piezoelectric elements 300 and a vibrating plate displaced by operation of the corresponding piezoelectric element 300 are referred to as “actuator devices”. While the resilient film 50, the insulating film 55, and the lower electrode film 60 serve as the vibrating plate in the foregoing example, the invention is not limited thereto. For example, the lower electrode film 60 alone may serve as the vibrating plate without the elastic film 50 and the insulating film 55. Alternatively, each piezoelectric element 300 may serve substantially as the vibrating plate.

The piezoelectric layers 70 are crystalline films composed of lead zirconate titanate (PZT), which is a piezoelectric oxide material with a polarized structure, having a perovskite structure formed above the lower electrode film 60. The piezoelectric layers 70 according to this embodiment have a rhombohedral crystal structure. The piezoelectric layers 70 composed of PZT are formed by stacking a plurality of piezoelectric films by a sol-gel method or a MOD method.

The upper electrode films 80, which function as individual electrodes of the piezoelectric elements 300, are connected to respective lead electrodes 90 composed of, for example, gold (Au), the lead electrodes 90 extending from an end near the ink supply channels 14 to the insulating film 55.

A protective substrate 30 including a reservoir portion 31 at least partially constituting the reservoir 100 is bonded to the channel-forming substrate 10 provided with the piezoelectric elements 300, i.e., to the lower electrode film 60, the resilient film 50, and the lead electrodes 90. In this embodiment, the reservoir portion 31 passes through the protective substrate 30 in the thickness direction and is arranged in the width direction of the pressure-generating chambers 12. Furthermore, as described above, the reservoir portion 31 communicates with the communicating portion 13 of the channel-forming substrate 10 to form the reservoir 100 serving as a common ink chamber for the pressure-generating chambers 12.

A piezoelectric-element-enclosing portion 32 having a cavity expanding to the extent that the motion of the piezoelectric elements 300 is not inhibited is formed in a region of the protective substrate 30 facing the piezoelectric elements 300.

The protective substrate 30 is provided with a through hole 33 passing through the protective substrate 30 in the thickness direction. Each of the lead electrodes 90 extending from a corresponding one of the piezoelectric elements 300 has an end portion exposed in the through hole 33.

A driving circuit 120 that operates the piezoelectric elements 300 arranged in parallel is mounted above the protective substrate 30. For example, a circuit board or a semiconductor integrated circuit (IC) may be used as the driving circuit 120. The driving circuit 120 is electrically connected to the lead electrodes 90 through interconnections 121 formed of conductive wires such as bonding wires.

A compliance substrate 40 including a seal film 41 and a stationary plate 42 is bonded to the protective substrate 30.

In such an inkjet recording head according to this embodiment, ink is fed from an ink port connected to an external ink-feeding unit (not shown) to fill the inside, i.e., from the reservoir 100 to the nozzle openings 21, of the head with the ink. Then a voltage is applied between the lower electrode film 60 and the upper electrode films 80 corresponding to the pressure-generating chambers 12 according to a recording signal from the driving circuit 120 to deform the resilient film 50, the lower electrode film 60, and the piezoelectric layers 70, thereby increasing the pressure in the pressure-generating chambers 12 and ejecting ink droplets from the nozzle openings 21.

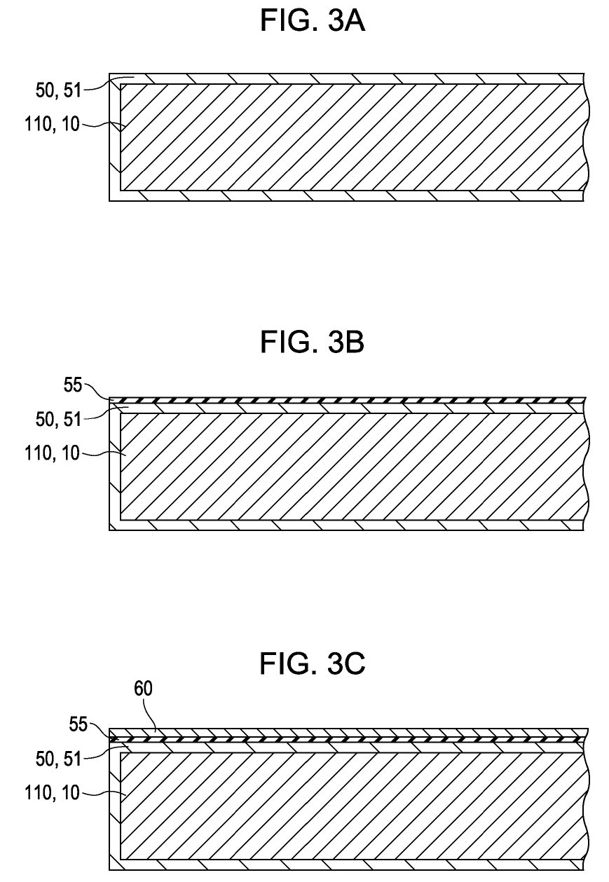

A method for producing such an ink jet recording head will be described below with reference to FIGS. 3A to 8B. FIGS. 3A to 8B illustrate a method for producing an ink jet recording head as an example of a liquid ejecting head according to the first embodiment of the invention and are cross-sectional views of a pressure-generating chamber in the longitudinal direction. As shown in FIG. 3A, a silicon dioxide film 51 composed of silicon dioxide (SiO₂) and constituting the resilient film 50 is formed on surfaces of a wafer 110 to be formed into a channel-forming substrate.

As shown in FIG. 3B, the insulating film 55 composed of zirconium oxide is formed above the resilient film 50 (silicon dioxide film 51).

As shown in FIG. 3C, the lower electrode film 60, which is a single platinum (Pt) layer or which is a film formed by stacking an iridium (Ir) layer above a platinum (Pt) layer and subjecting the layers to alloying is formed.

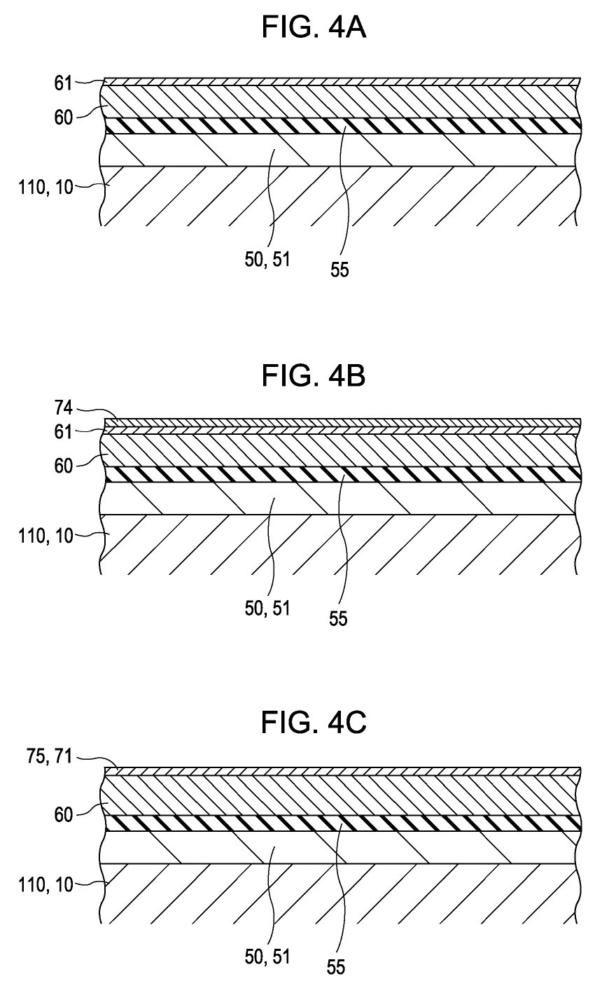

As shown in FIG. 4A, a titanium seed layer 61 composed of titanium (Ti) is formed above the lower electrode film 60. In this embodiment, the titanium seed layer 61 has a thickness of about 4 nm. The titanium seed layer 61 is preferably amorphous. Specifically, the X-ray diffraction intensity (XRD intensity) of the titanium seed layer 61, in particular, the XRD intensity from the (002) face is preferably substantially zero. When the titanium seed layer 61 is amorphous, the titanium seed layer 61 has an increased film density. This results in a reduction in the thickness of an oxide film formed above the surface of the titanium seed layer 61, leading to more satisfactory crystal growth of the piezoelectric layer 70.

The arrangement of the titanium seed layer 61 above the lower electrode film 60 makes it possible to control the preferred orientation direction of the piezoelectric layer 70 to the [100] or [111] direction in forming the piezoelectric layer 70 above the lower electrode film 60 with the titanium seed layer 61 provided therebetween, thereby providing the piezoelectric layer 70 suitable as an electromechanical transducer. The titanium seed layer 61 serves as a seed that promotes the crystallization of the piezoelectric layer 70. After sintering the piezoelectric layer 70, the titanium seed layer 61 diffuses into the piezoelectric layer 70.

The lower electrode film 60 and the titanium seed layer 61 may be formed by, for example, DC magnetron sputtering.

Next, the piezoelectric layer 70 composed of lead zirconate titanate (PZT) is formed. In this embodiment, the piezoelectric layer 70 is formed by a sol-gel method. In other words, a sol in which metal organic materials are dissolved or dispersed in a solvent is applied to the titanium seed layer 61, dried, and fired at a high temperature to form the piezoelectric layer 70. A method for forming the piezoelectric layer 70 is not limited to the sol-gel method but may be metal-organic decomposition (MOD).

A specific procedure for forming the piezoelectric layer 70 will be described below. As shown in FIG. 4B, a piezoelectric precursor film 74, which is a PZT precursor film, is formed above the lower electrode film 60 (titanium seed layer 61). That is, a sol (solution) containing titanium (Ti), zirconium (Zr), and lead (Pb) is applied to the channel-forming substrate 10 provided with the lower electrode film 60 (application substep). The piezoelectric precursor film 74 is heated to a predetermined temperature and dried for a predetermined period of time (drying substep). For example, in this embodiment, the piezoelectric precursor film 74 can be dried at 150° C. to 170° C. for 5 to 10 minutes.

The dry piezoelectric precursor film 74 is heated to a predetermined temperature and maintained for a predetermined period of time to perform calcination (calcination substep). For example, in this embodiment, the piezoelectric precursor film 74 is calcined by heating the film to 300° C. to 400° C. and maintaining the film for about 5 to 10 minutes. The calcination defined here indicates the elimination of organic components contained in the piezoelectric precursor film 74 by converting the organic components into, for example, NO₂, CO₂, and H₂O. In the calcination substep, the heating rate is preferably set at 15° C./s or more.

As shown in FIG. 4C, the piezoelectric precursor film 74 is heated to a predetermined temperature and maintained for a predetermined period of time to crystallize the film, thereby forming a piezoelectric film 75 (sintering substep). In this embodiment, the piezoelectric film 75 as the first layer is referred to as a first piezoelectric layer 71. In this sintering substep, sintering is performed at a temperature lower than a temperature (680° C. to 850° C.) at which the piezoelectric precursor films 74 as the third and subsequent layers described below are fired (details will be described below). Specifically, the piezoelectric precursor film 74 as the first layer is preferably heated at 630° C. to 680° C. Furthermore, in the sintering substep, the heating rate is preferably set at 90 to 110° C./s.

The thickness of the piezoelectric precursor film 74 as the first layer formed above the titanium seed layer 61 in the application substep is not particularly limited. Preferably, the piezoelectric precursor film 74 as the first layer is formed by application in such a manner that the first piezoelectric layer 71 after sintering has a thickness smaller than those of the piezoelectric films 75 as the third or subsequent layers. In this embodiment, the sol is applied in such a manner that the first piezoelectric layer 71 after the sintering substep has a thickness 5 to 40 times that of the titanium seed layer 61, so that the piezoelectric precursor film 74 as the first layer is formed.

Examples of a heater that can be used in the drying substep, the calcination substep, and the sintering substep include a hot plate and a rapid thermal processing (RTP) system in which heating is performed by irradiation with infrared rays using an infrared lamp.

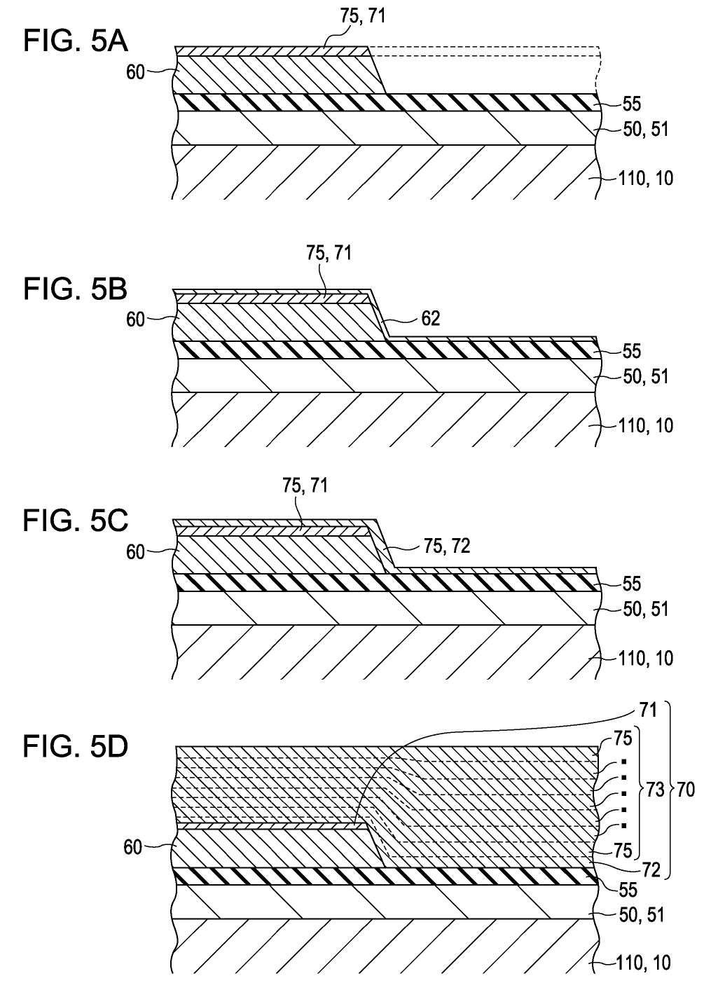

As shown in FIG. 5A, after the first piezoelectric layer 71 is formed above the lower electrode film 60, the lower electrode film 60 and the first piezoelectric layer 71 are simultaneously patterned in such a manner that side faces thereof are tilted. The lower electrode film 60 and the first piezoelectric layer 71 can be patterned by dry etching such as ion milling.

For example, in the case where patterning is performed after the formation of the titanium seed layer 61 above the lower electrode film 60 and then the piezoelectric film 75 as the first layer, the titanium seed layer 61 is degraded because the lower electrode film 60 is patterned by a photolithographic process, ion milling, and ashing. In this case, even if the piezoelectric film 75 is formed above the degraded titanium seed layer 61, the piezoelectric film 75 as the first layer does not have good crystallinity. The crystal growth of the piezoelectric films 75 as the second or subsequent layers formed above the piezoelectric film 75 as the first layer is affected by the crystalline state of the piezoelectric film 75 as the first layer. Thus, the piezoelectric layer 70 having good crystallinity cannot be formed. Furthermore, in the case where the lower electrode film 60 is patterned and then the piezoelectric film 75 as the first layer is fired, there are a region where the lower electrode film 60 is present as an underlying film and a region where the lower electrode film 60 is not present as the underlying film. Thus, the piezoelectric film 75 as the first layer cannot be uniformly heated in the planar direction due to the presence or absence of the underlying film, possibly resulting in nonuniform crystallinity.

In contrast, in the case where the piezoelectric film 75 as the first layer is formed above the lower electrode film 60 and then they are simultaneously patterned, the piezoelectric layers 70 having good crystallinity can be formed.

As shown in FIG. 5B, an intermediate titanium seed layer 62 composed of titanium (Ti) is formed above the entire surface of the wafer 110 including the first piezoelectric layer 71. The piezoelectric film formation step including the above-described application, drying, calcination, and sintering substeps is performed to form the piezoelectric film 75 as the second layer as shown in FIG. 5C. The piezoelectric film 75 as the second layer is referred to as a second piezoelectric layer 72. In this sintering substep, sintering is performed at a temperature lower than a temperature (680° C. to 850° C.) at which the third and subsequent layers are formed by sintering (details will be described below) in the same way as the piezoelectric precursor film 74 as the first layer. Specifically, the piezoelectric precursor film 74 is preferably heated at 630° C. to 680° C. Furthermore, in the sintering substep, the heating rate is preferably set at 90 to 110° C./s.

The thickness of the piezoelectric precursor film 74 formed above the intermediate titanium seed layer 62 in the application substep is not particularly limited. Preferably, the piezoelectric precursor film 74 as the second layer is formed by application in such a manner that the second piezoelectric layer 72 after sintering has a thickness smaller than those of the piezoelectric films 75 as the third or subsequent layers. In this embodiment, the sol is applied in such a manner that the second piezoelectric layer 72 after the sintering substep has a thickness 5 to 40 times that of the intermediate titanium seed layer 62, so that the piezoelectric precursor film 74 as the second layer is formed.

As shown in FIG. 5D, the piezoelectric film formation step including the application, drying, calcination, and sintering substeps is repeatedly performed above the second piezoelectric layer 72 to form the plurality of piezoelectric films 75. The piezoelectric films 75 as the third and subsequent layers are referred to as a third piezoelectric layer 73. In the sintering substep, sintering is performed at a temperature higher than a temperature at which the piezoelectric precursor films 74 as the first and second layers are formed by sintering. Specifically, the piezoelectric precursor film 74 as the third and subsequent layers is preferably heated at 680° C. to 850° C. Furthermore, in the sintering substep, the heating rate is preferably set at 90 to 110° C./s. In the application substep, each of the piezoelectric precursor films 74 as the third and subsequent layers has a thickness of 0.1 μm.

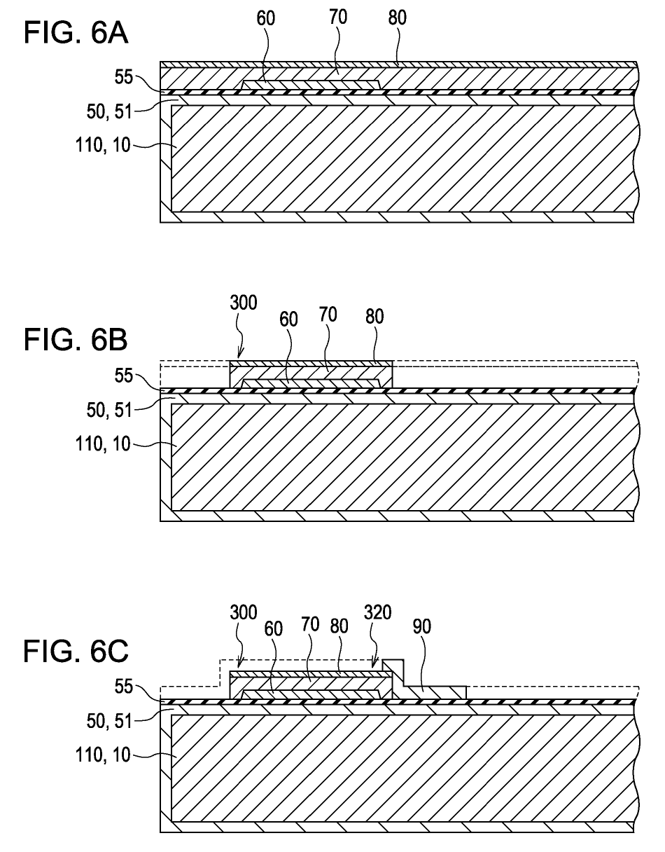

As shown in FIG. 6A, the upper electrode film 80 composed of, for example, iridium (Ir) is formed across the piezoelectric layer 70.

As shown in FIG. 6B, the piezoelectric layer 70 and the upper electrode film 80 are patterned to form the piezoelectric elements 300 in regions corresponding to the pressure-generating chambers 12. The piezoelectric layer 70 and the upper electrode film 80 can be patterned by dry etching such as reactive ion etching or ion milling.

Next, the lead electrodes 90 are formed. Specifically, as shown in FIG. 6C, for example, a gold (Au) film is formed above the entire surface of the wafer 110. The gold film is patterned with respect to each piezoelectric element 300 using a mask pattern (not shown) composed of, for example, a resist, thereby forming the lead electrodes 90.

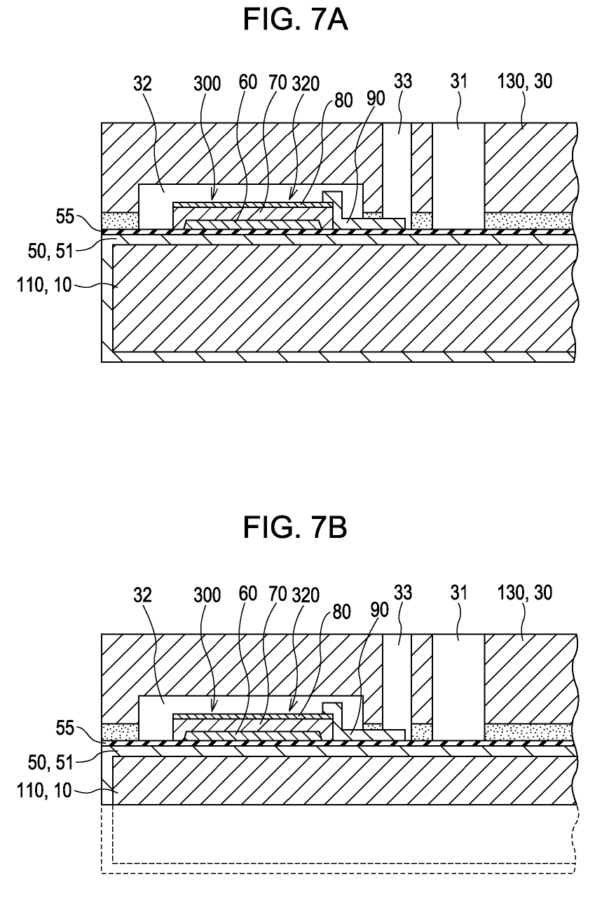

As shown in FIG. 7A, a silicon wafer 130 to be formed into the plurality of protective substrates 30 is bonded to the piezoelectric element 300 side of the wafer 110 to be formed into a channel-forming substrate.

Next, as shown in FIG. 7B, the thickness of the wafer 110 to be formed into a channel-forming substrate is reduced to a predetermined thickness.

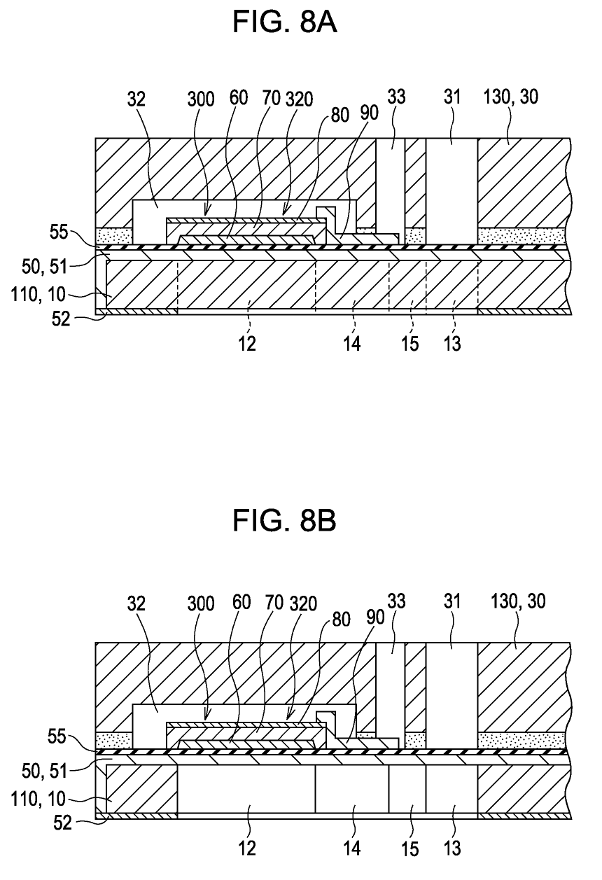

As shown in FIG. 8A, a mask film 52 is formed above the wafer 110 to be formed into a channel-forming substrate and patterned so as to have a predetermined pattern. As shown in FIG. 8B, the wafer 110 to be formed into a channel-forming substrate is subjected to anisotropic etching (wet etching) with the mask film 52 using an alkaline solution such as a KOH solution, thereby forming the pressure-generating chambers 12, the communicating portion 13, the ink supply channels 14, the communicating channels 15, and the like corresponding to the piezoelectric elements 300.

Unnecessary portions at peripheries of the wafer 110 to be formed into a channel-forming substrate and the wafer 130 to be formed into the protective substrate are removed by cutting such as dicing. The nozzle plate 20 including the nozzle openings 21 is bonded to a side of the wafer 110 opposite the side adjacent to the wafer 130. The compliance substrate 40 is bonded to the wafer 130. The wafer 110 is separated into the channel-forming substrate 10 having a single chip size as shown in FIG. 1, thereby forming an ink jet recording head according to this embodiment.

As described above, in the piezoelectric layer 70 of the ink jet recording head according to this embodiment, the first piezoelectric layer 71 and the second piezoelectric layer 72 are fired at a temperature lower than a temperature at which the third piezoelectric layer 73 is formed by sintering. This makes it possible to prevent the formation of an unstable composition phase in the vicinity of the interface between the first piezoelectric layer 71 and the second piezoelectric layer 72. This is based on findings described below.

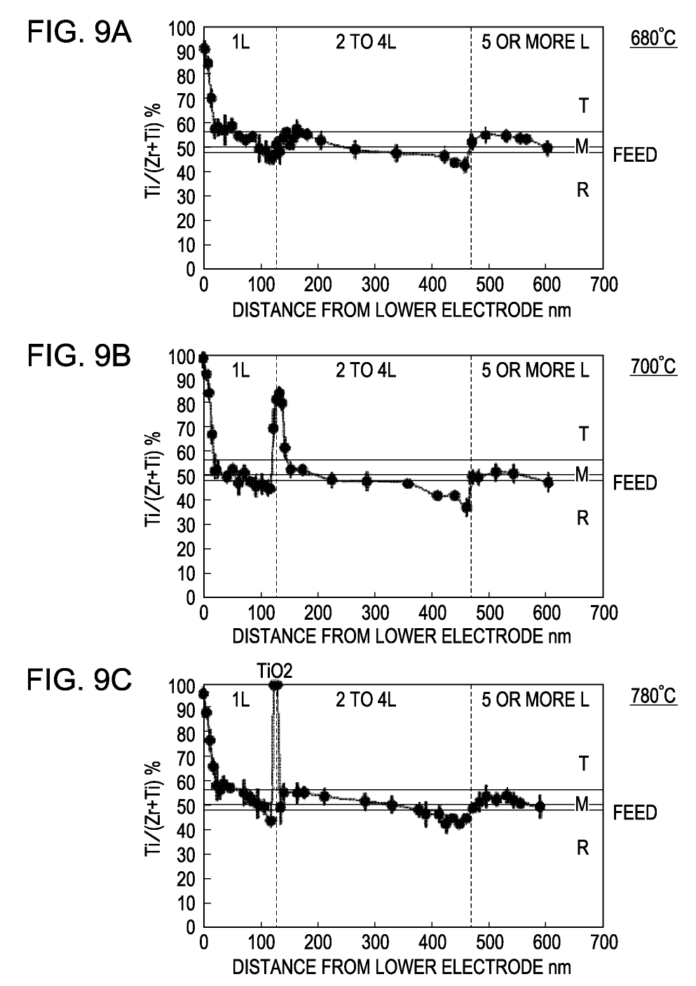

FIGS. 9A to 9C are graphs each showing the relationship between the titanium concentration in the piezoelectric layer and the distance from the lower electrode. In samples shown in FIGS. 9A to 9C, the applied sol has a thickness of 0.1 μm, and the piezoelectric film formation step including the application, drying, calcination, and sintering substeps is repeatedly performed. With respect to the sintering temperature in the sintering substep, the sample shown in FIG. 9A is fired at 680° C., the sample shown in FIG. 9B is fired at 700° C., and the sample shown in FIG. 9C is fired at 780° C.

In each of the graphs, the horizontal axis represents the distance from the lower electrode in the thickness direction, and the vertical axis represents the ratio of titanium (Ti) to zirconium (Zr), i.e., the proportion of titanium (titanium concentration) in total molar amount of zirconium and titanium. In the figures, “1L” represents the piezoelectric film as the first layer formed above the lower electrode. Similarly, “2 or more L” represents the piezoelectric film as the second or subsequent layer.

As shown in FIG. 9A, when the sample is fired at 680° C., an unstable composition phase having a very high titanium concentration is not formed (at a distance from the lower electrode of about 120 nm in the figure) in the vicinity of the interface between the piezoelectric film as the first layer and the piezoelectric film as the second layer. In contrast, as shown in FIGS. 9B and 9C, when the samples are fired at 700° C. and 780° C., unstable composition phases having very high titanium concentrations are formed in the vicinity of the interface between the piezoelectric film as the first layer and the piezoelectric film as the second layer. The results demonstrate that the formation of the unstable composition phase depends on the sintering temperature.

To produce an actuator device having satisfactory displacement properties, preferably, the titanium concentration lies on line M (a titanium concentration of about 50%) shown in FIG. 9A. However, as shown in FIG. 9A, in the piezoelectric film as the first layer, the titanium concentration exceeds line M and is about 60%, thereby slightly reducing the displacement properties of the actuator device.

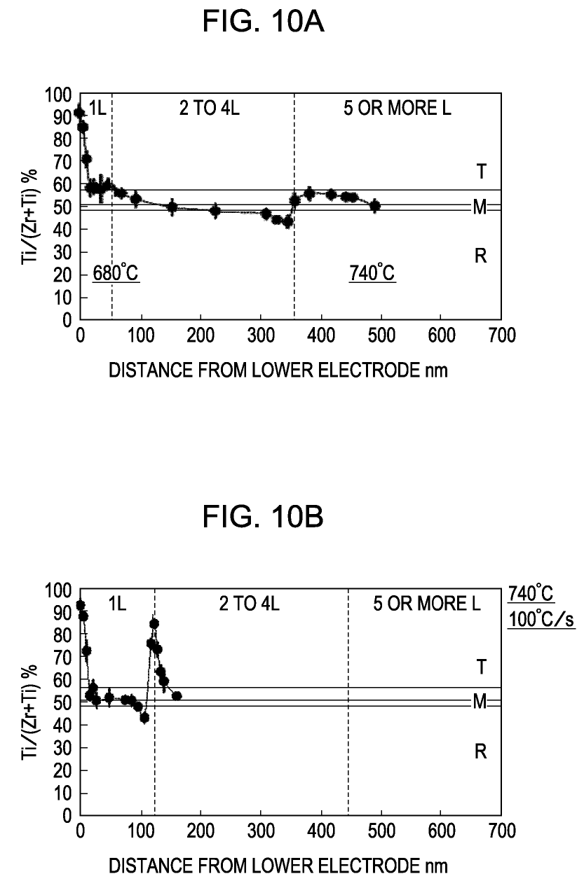

The piezoelectric layer of an actuator produced according to the invention on the basis of the foregoing findings will be described below. FIG. 10A is a graph showing the relationship between the titanium concentration in the piezoelectric layer and the distance from the lower electrode according to this embodiment. FIG. 10B is a graph showing the relationship between the titanium concentration in the piezoelectric layer and the distance from the lower electrode according to the related art. The vertical and horizontal axes in these graphs are the same as in FIGS. 9A to 9C. The piezoelectric layer according to the related art is formed under conditions in which the applied sol has a thickness of 0.1 μm, the piezoelectric film formation step including the application, drying, calcination, and sintering substeps is repeatedly performed, and the piezoelectric films are fired at 740° C.

As shown in FIG. 10A, the titanium concentration in the piezoelectric layer according to this embodiment is maximized (about 90%) in the vicinity of the lower electrode 60 and decreases gradually with decreasing distance from the interface between the first piezoelectric layer 71 (1L) and the second piezoelectric layer 72 (2L). The titanium concentration in the vicinity of the interface is about 60% in this embodiment. In contrast, as shown in FIG. 10B, in the piezoelectric layer according to the related art, an unstable composition phase having a high titanium concentration is formed between the first piezoelectric layer (1L) and the second piezoelectric layer (2L). Therefore, in the method for producing an actuator device according to this embodiment, such an unstable composition phase is not formed in the vicinity of the interface between the first piezoelectric layer 71 and the second piezoelectric layer 72. Thus, the actuator device has stable displacement properties, resulting in a liquid ejecting head having satisfactory liquid ejecting properties.

In the piezoelectric layer according to the related art, the titanium concentration in the first piezoelectric layer is about 50% in the middle of the thickness of the layer and sharply increases in the vicinity of the interface between the first piezoelectric layer and the second piezoelectric layer. This results in the stress difference between the first piezoelectric layer and the second piezoelectric layer, thus easily causing delamination at the interface. In contrast, the piezoelectric layer according to this embodiment does not have a sharp change in titanium concentration, thus eliminating the occurrence of a stress difference or delamination. Therefore, it is possible to provide a highly reliable actuator device.

As described above, when the first piezoelectric layer 71 and the second piezoelectric layer 72 are fired at 630° C. to 680° C., the titanium concentration is about 60%. This results in a slight reduction in displacement properties of the resulting actuator device. However, since each of the first piezoelectric layer 71 and the second piezoelectric layer 72 has a thickness smaller than that of the third piezoelectric layer 73, a region of the piezoelectric layer 70 having reduced displacement properties can be minimized.

The first piezoelectric layer 71 has a thickness 5 to 40 times that of the titanium seed layer 61. This thickness is a value such that the titanium concentration is about 60% in the vicinity of the interface between the first piezoelectric layer 71 and the second piezoelectric layer 72 resulting from the diffusion of titanium from the titanium seed layer 61 into the first piezoelectric layer 71 during the sintering substep.

In this embodiment, with respect to the piezoelectric layer 70, the precursor films for forming the first piezoelectric layer 71 and the second piezoelectric layer 72 are fired at a temperature lower than a temperature at which the third piezoelectric layer is formed by sintering. This makes it possible to prevent the formation of the unstable composition phase in the piezoelectric layer 70, thereby improving the displacement properties and reliability of an actuator device. Furthermore, the formation of the first piezoelectric layer 71 and the second piezoelectric layer 72 each having a thickness smaller than that of the third piezoelectric layer 73 results in the suppression of a reduction in the displacement properties of an actuator device due to the fact that the first piezoelectric layer 71 and the second piezoelectric layer 72 are fired at a low temperature. This results in an ink jet recording head having improved ink ejecting properties (liquid ejecting properties) and reliability.

### Other Embodiments

While an embodiment of the invention has been described, the basic structure and procedure of the invention are not limited to thereto. For example, in the first embodiment described above, after the formation of the lower electrode film 60 and the first piezoelectric layer 71, they are simultaneously patterned. The invention is not particularly limited thereto. For example, after the formation of the piezoelectric layer 70 and the upper electrode film 80, patterning may be performed.

In the foregoing first embodiment, the (110)-oriented single-crystal silicon substrate is exemplified as the channel-forming substrate 10. The channel-forming substrate 10 is not particularly limited thereto. For example, a (100)-oriented single-crystal silicon substrate may be used. Alternatively, an SOI substrate or a glass substrate may be used.

In the foregoing first embodiment, the sols having different ratios of titanium to zirconium are used for forming the first piezoelectric layer 71 and the second piezoelectric layer 72. The invention is not particularly limited thereto. For example, sols having the same ratio of titanium to zirconium may be used for forming the first piezoelectric layer 71 and the second piezoelectric layer 72.

In the first embodiment described above, an ink jet recording head is exemplified as a liquid ejecting head. The invention is directed to all liquid ejecting heads and, of course, can also be applied to liquid ejecting heads that eject liquids other than ink. Examples of other liquid ejecting heads include various recording heads used for image-recording devices such as printers; colorant ejecting heads used in the production of color filters for liquid crystal displays and the like; electrode-material ejecting heads used for forming electrodes in organic EL displays, field emission displays (FEDs), and the like; and bioorganic-material ejecting heads used for the production of biochips.

The invention is not limited to the method for producing an actuator device mounted on a liquid ejecting head such as an ink jet recording head but may be applied to a method for producing an actuator device mounted on another apparatus.

What is claimed is:

1. A method for producing an actuator device, comprising:
forming a lower electrode above a substrate;
forming a piezoelectric layer including a plurality of piezoelectric films above the lower electrode by repeatedly forming a piezoelectric film by sintering a piezoelectric precursor film containing titanium, zirconium, and lead; and
forming an upper electrode above the piezoelectric layer,
wherein in forming the piezoelectric layer, the method further includes:
forming a titanium seed layer above the lower electrode and crystallizing a piezoelectric precursor film by sintering to form a first piezoelectric layer above the titanium seed layer;
forming an intermediate titanium seed layer above the first piezoelectric layer and crystallizing a piezoelectric precursor film by sintering to form a second piezoelectric layer above the intermediate titanium seed layer; and
stacking at least one piezoelectric precursor film above the second piezoelectric layer and crystallizing the at least one piezoelectric precursor film by sintering at a temperature higher than a temperature at which the first and second piezoelectric layers are formed by sintering, so that a third piezoelectric layer is formed.

2. The method according to claim 1,
wherein the first piezoelectric layer has a thickness 5 to 40 times that of the titanium seed layer,
the second piezoelectric layer has a thickness 5 to 40 times that of the intermediate titanium seed layer, and
the first and second piezoelectric layers are formed by sintering at 630° C. to 680° C.

3. The method according to claim 1, further comprising:
after forming the first piezoelectric layer, simultaneously patterning the lower electrode and the first piezoelectric layer,
wherein the intermediate titanium seed layer is formed above the substrate including the patterned first piezoelectric layer.

4. A method for producing a liquid ejecting head,
wherein the liquid ejecting unit is formed by the method for producing an actuator device according to claim 1.
